(19) United States
(12) Patent Application Publication
(10) Pub. No.: US 2012/0261840 A1
(43) Pub. Date: Oct. 18, 2012

(54) SEMICONDUCTOR DEVICE

(75) Inventors: Tetsuya Akimoto, Kanagawa (JP); Akimori Hayashi, Kanagawa (JP)

(73) Assignee: RENESAS ELECTORNICS CORPORATION, Kawasaki-shi (JP)

(21) Appl. No.: 13/531,165

(22) Filed: Jun. 22, 2012

Related U.S. Application Data
(62) Division of application No. 12/458,217, filed on Jul. 2, 2009.

(30) Foreign Application Priority Data
Jul. 4, 2008 (JP) 2008-176063

(51) Int. Cl. H01L 23/48

(52) U.S. Cl. 257/782; 257/E23.01

(57) ABSTRACT

A semiconductor device includes an interposer, a semiconductor chip mounted on the interposer, a first wiring pattern formed on the interposer, the first wiring pattern including a first contact coupled to a bonding wire from the semiconductor chip and a second contact coupled to an external terminal of the interposer, and a second wiring pattern formed adjacent to the first wiring pattern on the interposer, the second wiring pattern including a third contact coupled to another bonding wire from the semiconductor chip and a fourth contact coupled to another external terminal of the interposer. The first contact is closer to the semiconductor chip than the third contact.

### REFERENCE TO RELATED APPLICATION

The present application is a Divisional application of U.S. patent application Ser. No. 12/458,217, filed on Jul. 2, 2009, which is based on and claims priority from Japanese patent application No. 2008-176063, filed on Jul. 4, 2008, the entire contents of which are incorporated herein by reference.

### TECHNICAL FIELD

The present invention relates to a semiconductor device, and particularly to a semiconductor device, embedded in a package, having the pad of a semiconductor chip and an external connection pattern of the package connected by wire bonding.

### BACKGROUND

As the performance of semiconductor integrated circuits improves, there is an increasing demand for high-speed signal processing. Because of this, in a semiconductor integrated circuit embedded in a package, the transmission loss of a high-speed signal between a pad of the semiconductor integrated circuit and an external connection terminal of the package needs to be reduced. Meanwhile, although the bonding wire structure is widely used as a low-cost IC package solution, it has generally been considered not suitable for semiconductor integrated circuit packages that input/output high-speed signals for which transmission loss becomes an issue. Although these are not solutions for transmission loss, the following prior arts are disclosed as semiconductor integrated circuits having a bonding wire structure and aiming at improved high-frequency characteristics.

FIG. 6 is a cross-sectional view of a main section of a semiconductor package described in Patent Document 1. In FIG. 6, the signal of a semiconductor chip is connected from a semiconductor chip 35 to a BGA ball 50 via a signal wire 38, a signal wiring 36, and a signal through hole 45. Meanwhile, GND (ground) of the semiconductor chip is connected from the semiconductor chip 35 to a BGA ball 52 via a GND wire 40, a ground core 31, and a GND through hole 48. Patent Document 1 states that the inductance of the ground path is reduced and the high-frequency characteristics are improved since the GND wire can be made shorter than the signal wire.

FIG. 7 is a cross-sectional view of a semiconductor device described in Patent Document 2. In Patent Document 2, a semiconductor chip 120 is connected to a BGA ball 116 via a bonding wire 122, a wiring pattern on a substrate, and a through hole plug 110. Patent Document 2 states that the high-frequency characteristics are improved by shortening the length of the bonding wire.

FIG. 8 is a cross-sectional view of a main section of a semiconductor device described in Patent Document 3. In Patent Document 3, a signal of a semiconductor chip 8 is connected from a bonding pad to a BGA ball 10 via a signal wire 15, a wiring pattern 3, a through hole 2, and a wiring pattern 6. Meanwhile, the power supply and GND are connected from the IC chip 8 to the BGA ball via the GND wire 16, a GND wiring, and a GND through hole 11. Patent Document 3 states that high-speed operation is realized by making the power supply and ground wiring shorter than the signal wiring, thereby reducing the inductance.

### Patent Document 1

Japanese Patent Kokai Publication No. JP-P2000-188359A

### Patent Document 2

Japanese Patent Kokai Publication No. JP-P2005-129904A

### Patent Document 3

Japanese Patent Kokai Publication No. JP-A-9-148476

### SUMMARY

The entire disclosure of above Patent Documents are incorporated herein by reference thereto. The following analyses on the related art is given in the light of the patent invention.

For semiconductor devices that deal with high-speed signals, it has become an important issue to reduce the transmission loss of the high-speed signals. The transmission loss not only causes distortion in the waveform of the high-speed signal, increasing signal transmission errors, but also generates electromagnetic radiation (a.k.a. radiation noise) in the surroundings, causing various problems. The prior arts described above do not solve these problems. Thus there is much to be desired in the art.

According to a first aspect of the present invention there is provided a semiconductor device which comprises a semiconductor chip, an interposer on which the semiconductor chip is mounted; and a signal wiring connected from a first pad provided on the semiconductor chip to a first external terminal via the interposer. The semiconductor device further comprises a return path wiring which forms a return path for the signal wiring and comprises a wiring pattern connected from a second external terminal provided adjacent to the first external terminal to a second pad provided adjacent to the first pad via the interposer. The signal wiring and the return path wiring are disposed substantially on the same plane. The signal wiring and the return path wiring intersect with each other at the intermediary.

According to a second aspect of the present invention, there is provided a semiconductor device which comprises a semiconductor chip and an interposer on which the semiconductor chip is mounted. The interposer comprises a first wiring pattern and a second wiring pattern respectively connected to an external terminal formed on the interposer. The first wiring pattern and the second wiring pattern are disposed adjacent to each other on the same plane layer of the interposer. The first wiring pattern has a first stitch to which one end of a first bonding wire is connected. The second wiring pattern has a second stitch to which one end of a second bonding wire is connected. The other end of the first bonding wire is connected to a signal pad of the semiconductor chip. The other end of the second bonding wire is connected to a ground pad or power supply pad of the semiconductor chip. The first stitch is disposed closer to the semiconductor chip than the second stitch is.

The meritorious effects of the present invention are summarized as follows.

According to a semiconductor device of the present invention, a magnetic field caused by an electric current is suppressed and the transmission loss of a high-speed signal can be reduced by having current loops formed by a signal wiring and a return path wiring intersect with each other at the intermediary, reversing the directions of magnetic fields caused by the current loops, and having the magnetic fields caused the current loops cancel each other.

### BRIEF DESCRIPTION OF THE DRAWINGS

FIG. 1 is a cross-sectional view of a main section of a semiconductor device in Exemplary Embodiment 1 of the present invention.

FIG. 2 is a plan view of the main section of the semiconductor device in Exemplary Embodiment 1 of the present invention.

FIG. 3 is a plan view of a main section of a wiring layer 2 in the semiconductor device in Exemplary Embodiment 1 of the present invention.

FIG. 4 is a drawing for explaining the flow of currents between an IC chip and a chip mounting surface of an interposer in FIG. 1.

FIG. 5 is a drawing for explaining the flow of currents from the IC chip to an external connection terminal of the interposer in FIG. 1.

FIG. 6 is a cross-sectional view of a main section of a semiconductor package described in Patent Document 1.

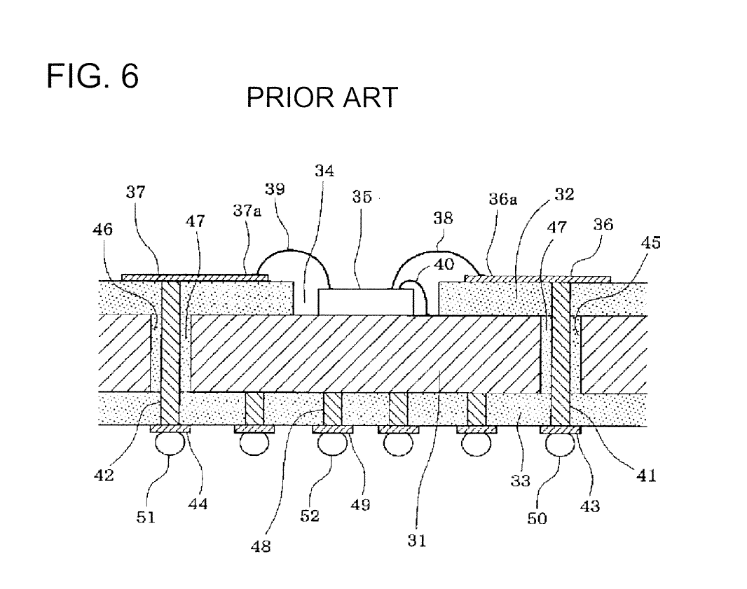

FIG. 7 is a cross-sectional view of a semiconductor device described in Patent Document 2.

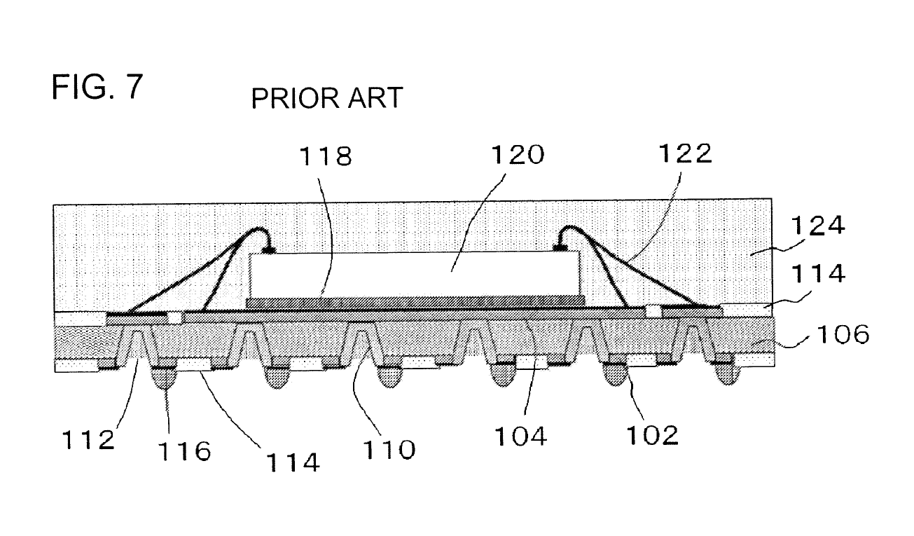

FIG. 8 is a cross-sectional view of a main section of a semiconductor device described in Patent Document 3.

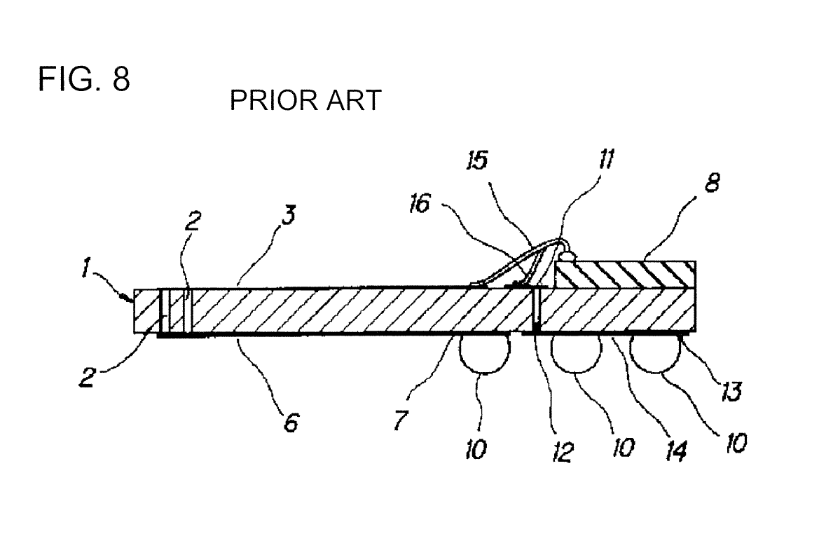

FIG. 9 is a cross-sectional view of a main section of a semiconductor device in another example of the present invention.

FIG. 10 is a plan view of the main section of the semiconductor device in the another example of the present invention.

FIG. 11 is a drawing for explaining the directions in which currents flow in FIG. 9.

FIG. 12 is a diagram of the analysis performed by the present inventor on a signal current and a return current in Patent Document 1.

FIG. 13 is a diagram of the analysis performed by the present inventor on the signal current and the return current in Patent Document 2.

FIG. 14 is a diagram of the analysis performed by the present inventor on the signal current and the return current in Patent Document 3.

### PREFERRED MODES

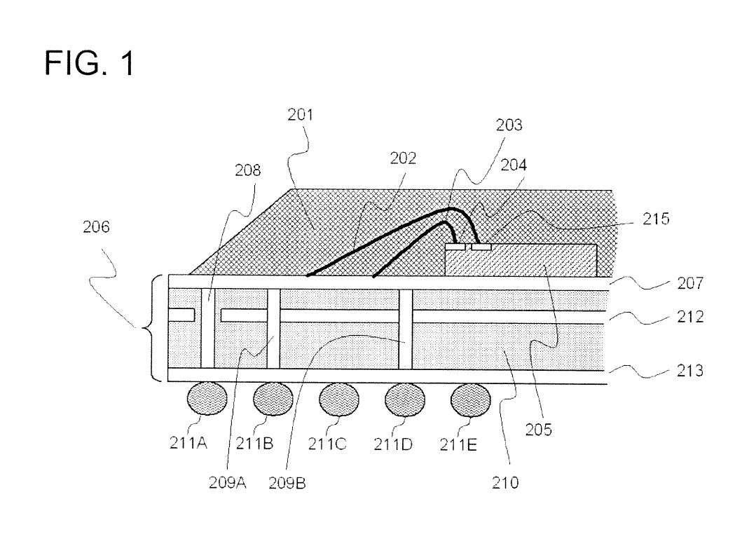

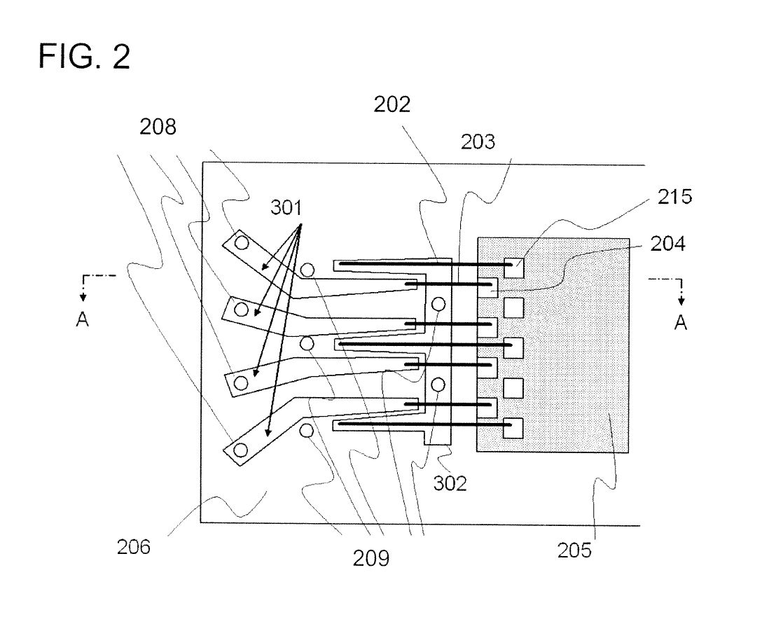

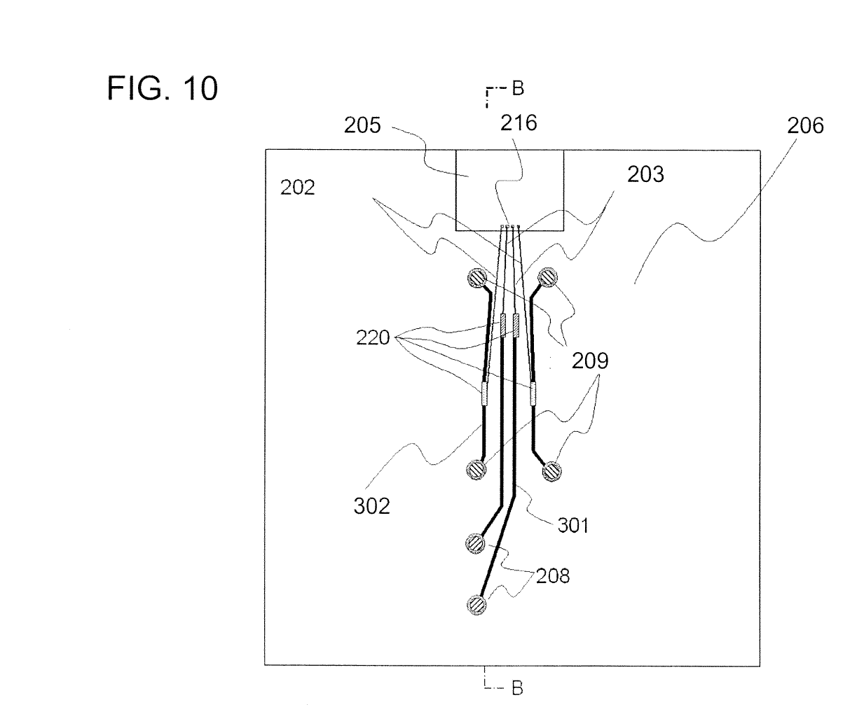

A mode of the present invention will be described with reference to the drawings as necessary. As shown in FIGS. 1, 5, 9, and 11, a semiconductor device of Mode 1 of the present invention comprises a semiconductor chip (IC chip) 205, an interposer 206 on which the semiconductor chip is mounted, a signal wiring (this signal wiring will be referred to as Wire 401 in the present description hereinafter), which is a signal current path 401 connected from a first pad 204 provided on the semiconductor chip to a first external terminal 211A via the interposer 206, and a return path wiring (this return path wiring will be referred to as Wire 402 in the present description hereinafter), which is a wiring pattern connected from a second external terminal 211B provided adjacent to the first external terminal 211A to a second pad 215 provided adjacent to the first pad 204 via the interposer 206 and is also a current return path (or simply return path) 402 for the signal wiring; the signal wiring (Wire 401) and the return path wiring (Wire 402) are substantially disposed on the same surface (a AA cross section in FIG. 2 or a BB cross section in FIG. 10); and the signal wiring and the return path wiring intersect at the middle. The configuration described above is able to make magnetic fields created by a current loop formed by the signal wiring (Wire 401) and the return path wiring (Wire 402) cancel each other out.

Further, in the semiconductor device of Mode 1, the signal wiring (Wire 401) includes a first bonding wire 203 that connects the first pad 204 and a signal wiring pattern 301 (first wiring pattern) provided on the interposer surface, on which the semiconductor chip is also mounted, and the return path wiring (Wire 402) includes a second bonding wire 202 that connects the second pad 215 and a return path wiring pattern 302 (second wiring pattern) provided on the interposer surface, on which the semiconductor chip is also mounted.

Further, the first bonding wire 203 and the second bonding wire 202 are configured so that one bonding wire is positioned lower and its length is shorter than the other.

Further, the first external terminal 211A and the second external terminal 211B are provided on the surface of the interposer 206 opposite to the semiconductor chip mounting surface, and the signal wiring (Wire 401) and the return path wiring (Wire 402) intersect in a wiring layer 1 (207) provided on the semiconductor chip mounting surface.

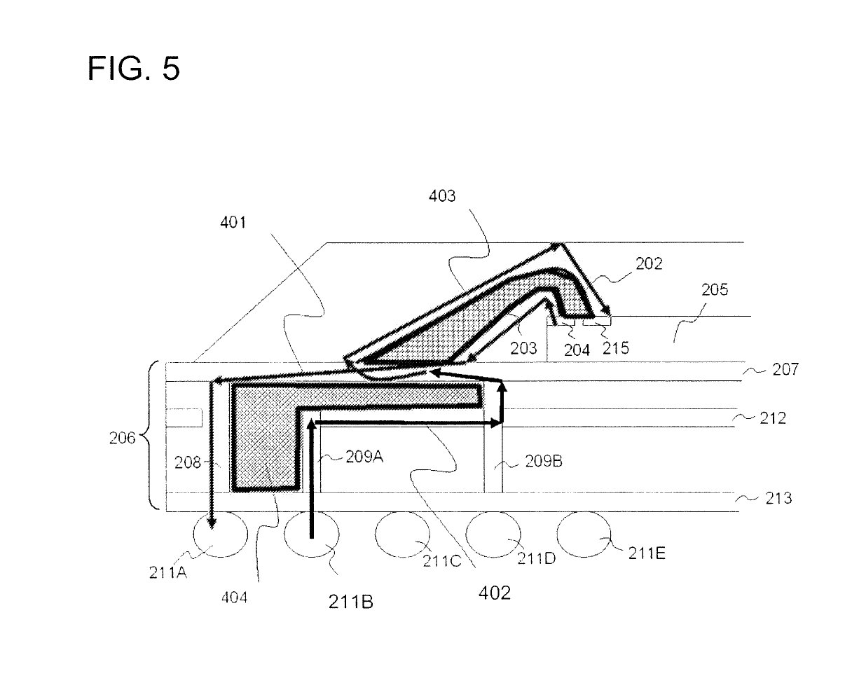

Further, as shown in FIG. 5, the current loop (the loop formed by the signal current path 401 and the current return path 402) is divided into two regions (403 and 404) by the intersection (crossing-over), and the cross sectional areas of these two regions are essentially equal to each other.

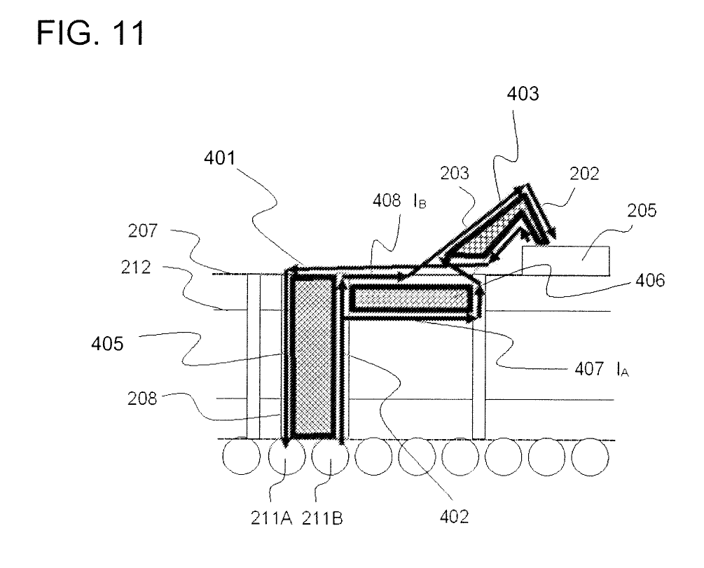

Further, as shown in FIG. 11, the return path wiring (Wire 402) is connected from the second external terminal 211B to the second pad (GND pad) via a plurality of paths (407 and 408), the return path of each path (407 and 408) and the signal wiring (Wire 401) are substantially provided on the same surface, and the signal wiring (Wire 401) respectively intersects with the return paths 407 and 408 at the middle so that the total sum of magnetic fields caused by the current loops formed by the signal wiring (Wire 401) and the return paths 407 and 408 becomes small.

According to the mode described above, the magnetic fields generated by the flow of the signal current and the return current can be suppressed and the transmission loss of a high-speed signal can be reduced.

The present invention will be described in detail using exemplary embodiments with reference to the drawings. Note that descriptions will be made assuming that the return path is a GND (ground) path in the following examples. In other words, cases where the return path wiring (Wire 402) is configured to be a GND wiring will be described.

### Exemplary Embodiment 1

FIG. 1 is a cross-sectional view of a main section of a semiconductor device in Exemplary Embodiment 1. The IC chip 205 mounted on the interposer 206. The signal pad (the first pad) 204 and the GND pad (ground pad) 215 provided on the IC chip are wire-bonded to the wiring layer 1 (207) of the interposer 206 by the signal wire (the first bonding wire) 203 and the GND wire (ground wire/the second bonding wire) 202 respectively. The signal wire 203 is positioned lower and its length is shorter compared to the GND wire 202. Further, GND through holes (vias) 209A and 209B and a signal through hole 208 are provided on the interposer 206 and they penetrate from the IC chip mounting surface of the interposer 206 to the opposite side. Out of these holes, at least one of the GND through hole 209B is connected to the GND wiring pattern 302 formed on the wiring layer 1 (207) in a place closer to the IC chip 205 than a stitch (connection point) of the signal wire 203 on the signal wiring pattern 301 formed on the wiring layer 1 (207) is. Further, the signal through hole 208 is positioned closer to an outer peripheral area of the interposer 206 than a stitch of the GND wire 202 on the GND wiring pattern 302 formed on the wiring layer 1 (207) is. Further, on the interposer 206, the wiring layer 1 (207), a wiring layer 2 (212), and a wiring layer 3 (213) are provided. Further, BGA balls 211A to 211E are provided on the surface of the interposer 206 opposite to the interposer mounting side. Here, the signal through hole 208 is connected to the BGA ball 211A independently from the wiring pattern formed on the wiring layer 3 (213). Similarly, the GND through holes 209A and 209B are respectively connected to the BGA balls 211B and 211D, independently from the wiring patterns formed on the wiring layer 3 (213). Further, the IC chip 205, the signal wire 203, and the GND wire 202 are covered with a mold resin 201. Further, interlayer insulating layers 210 are formed between the wiring layers (207, 212, and 213).

FIG. 2 is a plan view of the main section of the semiconductor device shown in FIG. 1 when viewed from the IC chip mounting surface. Note that a cross-sectional view along line A-A in FIG. 2 is FIG. 1. Further, the mold resin is omitted in FIG. 2. In FIG. 2, the signal wiring pattern 301 connects from the connection point (stitch) of the signal wire 203 to the interposer to the signal through holes 208 placed on the outer peripheral area of the interposer 206. Further, the GND wiring pattern 302 connects from the connection point (stitch) of the GND wire 202 to the interposer to the GND through holes 209 placed on the side of the IC chip. Here, out of these GND through holes 209, the GND through holes closer to the IC chip correspond to 209B in FIG. 1, and those closer to the interposer 206 correspond to 209A in FIG. 1. Therefore, the GND wiring pattern 302 connects from the connection point (stitch) of the GND wire 202 to the interposer to the GND through holes 209B. Further, the signal wiring pattern 301 and the GND wiring pattern 302 are both formed on the wiring layer 1.

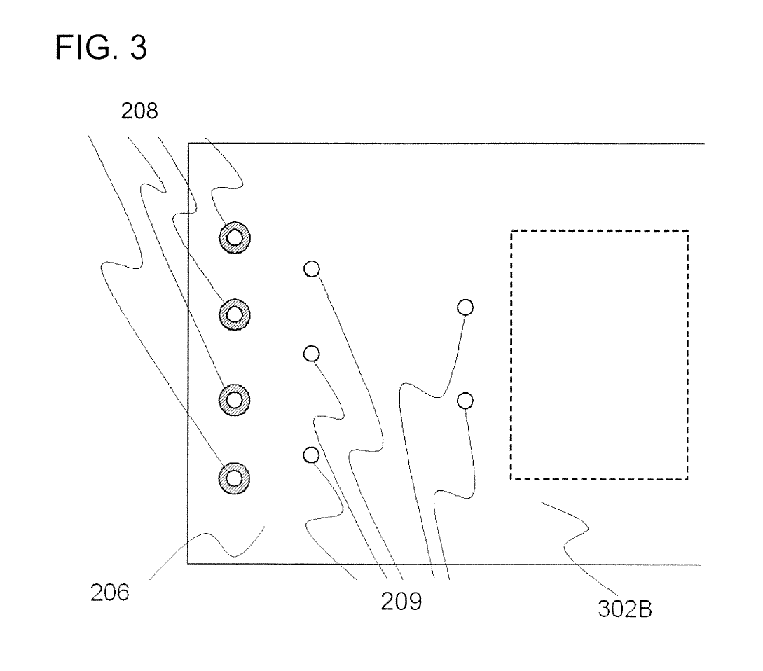

FIG. 3 is a plan view of a main section of the wiring layer 2 (212) in the semiconductor device in FIG. 1. It is a drawing of the second wiring layer from the top of the IC interposer, which is an exemplary embodiment of the present invention. This second wiring layer has a GND plane structure and a GND wiring covers the entire configuration described above. In other words, the GND through holes 209A and 209B are electrically connected to the GND plane (302B). Meanwhile, the signal through holes (208) are not electrically connected to the GND plane (302B).

As shown in FIGS. 1, 2, and 3, the signal wiring (Wire 401) forms the signal current path (401) that goes through the signal pad 204 of the IC chip 205, the signal wire 203, the stitch on the signal wiring pattern (301) formed on the wiring layer 1 (207) and the signal wiring pattern (301), the signal through holes 208, and the BGA ball 211A. Similarly, the GND wiring, i.e., the return path wiring (Wire 402) forms the current return path (402) that goes through the GND pad 215 of the IC chip 205, the GND wire 202, the stitch on the GND wiring pattern (302) formed on the wiring layer 1 (207) and the GND wiring pattern (302), the GND through holes 209B, the GND plane (302B) formed on the wiring layer 2 (212), and the BGA ball 211B. Further, the signal wiring pattern (301) and the GND wiring pattern (302) are disposed on the wiring layer (207) adjacent to each other with space interposed therebetween, as shown in FIG. 2.

Therefore, in the order of proximity to the IC chip 205, the GND through holes 209B, the stitch of the signal wiring pattern 301 to which the signal wire 203 is connected, the stitch of the GND wiring pattern 302 to which the GND wire 202 is connected, and the signal through holes 208 are disposed, and the signal wiring pattern 301 and the GND wiring pattern 302 connecting between the stitches and the through holes corresponding to the signal and GND respectively are formed on the wiring layer 1 (207). In this configuration, the signal wiring (Wire 401) and the return path wiring (Wire 402) intersect (at the intermediary, preferably at the middle of the paths) on the wiring layer 1 (207) provided on the semiconductor chip mounting surface.

Before the description of the operation of Exemplary Embodiment 1, the return path will be explained. When a signal current flows through a signal path, an AC magnetic field is generated in the surrounding space according to Ampère's law. This means that the energy flowing through the signal path is diffused into the surroundings and causes a transmission loss. In order to present this transmission loss, a wiring connected to a fixed potential such as a GND potential is provided in parallel to the signal path through which the signal current flows. This is the return path. If the return path is provided, based on the AC magnetic field generated by the flow of the current through the signal path, the induced electromotive force causes a current to flow through the return path according to Faraday's Law. This current is the return current, which cancels out and reduces the AC magnetic field present in the surrounding space. Then the energy diffused into the surrounding decreases and the transmission loss is reduced. This idea of the return path has already been used in design methods in high-speed signal transmission.

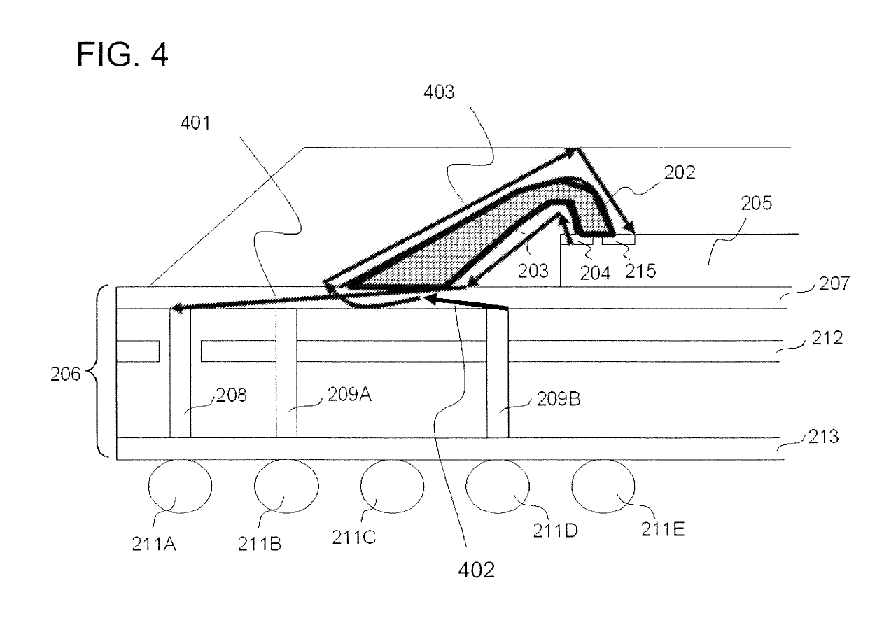

FIG. 4 is a drawing for explaining routes through which the signal current and the return current flow between the wiring pattern on the chip mounting surface of the interposer 206 and the pad of the IC chip in Exemplary Embodiment 1. As shown in FIG. 4, the signal current path 401 through which the signal current (the signal current flowing through the signal current path 401 is referred to as I401 hereinafter) flows from the signal pad 204 to the wiring pattern on the chip mounting surface via the signal wire 203 is formed and on the other hand, the current return path 402 through which the return current (the return current flowing through the current return path 402 is referred to as I402 hereinafter) flows from the wiring pattern on the chip mounting surface to the GND pad via the GND wire is formed. Note that the signal wire 203 is positioned lower and its length is shorter compared to the GND 202 for reasons related to the mounting process. Therefore, the region 1 (403) exists between the route of the signal current (I401) and the route of the return current (I402). When the amount of the signal current and the return current is I1 and the area of the region 1 surrounded by these currents is ΔS1, the magnetic moment Mm of the AC magnetic field present in the surrounding space is expressed by the following equation (1), according to Biot-Savart law. Here, μ denotes the magnetic permeability.

Mₘ=μI₁×ΔS₁ Equation (1)

Here is the current I1 is always finite and the area ΔS1, determined by reasons related to the mounting process, is always finite. Generally speaking, when wire bonding is performed, it is impossible to completely eliminate the region between the signal wiring and the return path wiring. Therefore, when only the region shown in FIG. 4 is considered, it may be impossible to avoid the generation of the magnetic field in the surrounding space in Exemplary Embodiment 1 according to Equation (1) above.

FIG. 5 is a drawing in which routes of the signal current and the return current to the external terminals (BGA balls) provided on the opposite side to the chip mounting surface are added to FIG. 4 described above in Exemplary Embodiment 1. As shown in FIG. 5, comparing the signal current path 401 and the current return path 402, the signal current path 401 is disposed closer to the IC chip 205 inside and the current return path 402 is disposed closer to the outer peripheral area of the package in the region above the surface of the interposer 206 on which the IC chip 205 mounted. However, the signal current path 401 and the current return path 402 intersect (cross-over) on the chip mounting surface of the interposer 206 and inside the interposer 206, the signal current path 401 is positioned closer to the outer peripheral side than the current return path 402. A region between the signal current path 401 and the current return path 402 inside the interposer 206 will be referred to as a region 2 (404). In other words, there are two regions surrounded by the signal current path 401 and the current return path 402: the region 1 (403) and the region 2 (404). Regarding the directions of the signal current flow and the return current flow surrounding each region, the currents flow in a clockwise direction in the region 1 (403) and in a counterclockwise direction in the region 2 (404). When the amounts of the currents flowing around the regions 1 and 2 are I1 and I2 respectively and the areas of the regions 1 and 2 surrounded by theses currents are ΔS1 and ΔS2 respectively, the magnetic moment Mm of the AC magnetic field present in the surrounding space is expressed by the following equation (2) according to Biot-Savart law.

Mₘ=μI₁×ΔS₁+μI₂×ΔS₂ Equation (2)

Here, since the currents I1 and I2 are vector volumes, their current values are identical, and the current directions are opposite to each other, the magnetic moment in sufficiently distant space, compared to the size of the IC package, can be rewritten as in the following equation (3) using I1.

|Mₘ|=μ|I₁|(ΔS₁−ΔS₂) Equation (3)

Therefore, the AC magnetic field generated in the surrounding space is reduced according to the difference in area between the regions 1 and 2, and as a result, the transmission loss of a high-speed signal can be reduced. Further, by designing so that the areas of the regions 1 and 2 are the same, the AC magnetic field in distant space can be minimized and electromagnetic radiation (a.k.a. radiation noise) can be reduced.

Further, the signal current path 401 and the current return path 402 are provided on the same surface. More concretely, the signal current path 401 and the current return path 402 are provided on the AA section in FIG. 2 or on the planes shown in FIGS. 1 and 5. Strictly speaking, since the signal current path 401 and the current return path 402 need to intersect, they are not exactly on the same plane. Further, there are many cases where they are not on the same plane for reasons related to the mounting process. However, even in these cases, the effects can be obtained as long as the signal current path 401 and the current return path 402 intersect at the intermediary (preferably at the middle) and they are directed so that the magnetic fields cancel each other.

### Exemplary Embodiment 2

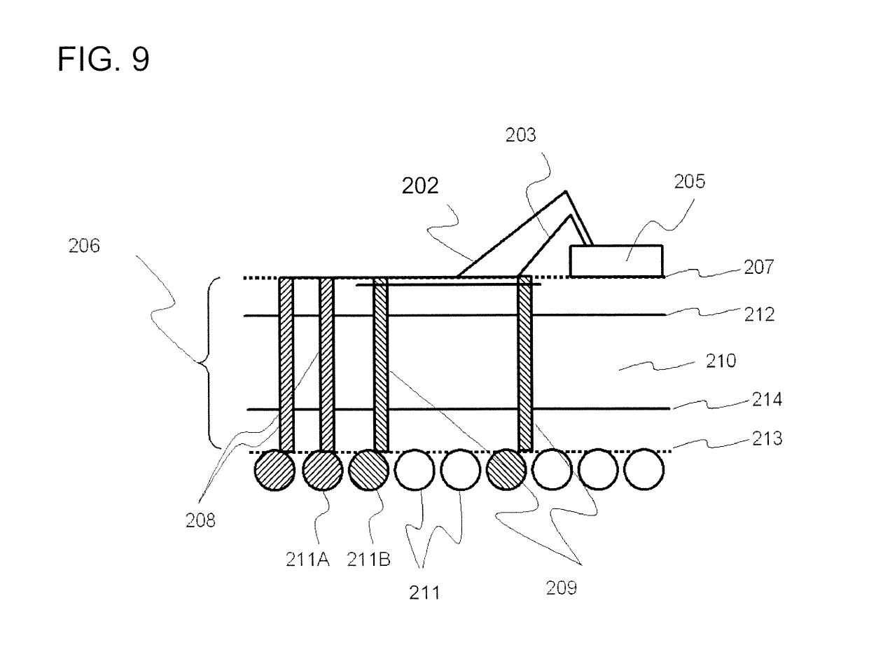

FIG. 9 is a cross-sectional view of a main section of a semiconductor device in Exemplary Embodiment 2. On the interposer 206, the wiring layer 1 (207), the wiring layer 2 (212), the wiring layer 3 (213), and a wiring layer 4 (214) are provided. Further, the interlayer insulating layers 210 are formed between the wiring layers (207, 212, 213, and 214). BGA balls 211 in FIG. 9 correspond to the BGA balls 211C to 211E in FIG. 1. The IC chip 205 is mounted on the interposer, and the IC chip 205 and the interposer 206 are wire-bonded by the signal wire 203 and the GND wire 202. The signal wire 203 is positioned lower and its length is shorter compared to the GND wire 202. Further, a plurality of the GND through holes 209 are provided on the interposer 206 and they penetrate from the chip mounting surface of the interposer to the opposite side. One of the plurality of the GND through holes 209 is positioned closer to the IC chip (inside) than the stitch of the signal wire 203 on the interposer is. Further, the other hole is positioned closer to the outside than the stitch of the signal wire 203 on the interposer is. The signal through hole 208 is positioned closer to the outer peripheral side than the stitch of the GND wire on the interposer is.

FIG. 10 is a plan view of the main section of the semiconductor device of Exemplary Embodiment 2 when viewed from the IC chip mounting surface. Note that a cross-sectional view along line B-B in FIG. 10 is FIG. 9. The signal wire 203 is connected to the signal through hole 208 via the signal wiring pattern 301 provided on the surface of the interposer. Further, the GND wire 202 is connected to the GND through hole via the GND wiring pattern 302 provided on the surface of the interposer. Here, one end of the signal wire 203 is connected to the signal pad of the IC chip 205, and the other end of the signal wire 203 is connected to a stitch 220 formed on the signal wiring pattern 301. Similarly, one end of the GND wire 202 is connected to the GND pad (ground pad) of the IC chip 205, and the other end of the GND wire 202 is connected to the stitch 220 formed on the GND wiring pattern 302.

Next, an operation in which a high-speed signal is transmitted through the signal wiring from a bonding pad 216 to the first external terminal (BGA ball) 211A via the signal wire 203, the signal wiring pattern 301, and the signal through hole 208 in the semiconductor device of Exemplary Embodiment 2 will be described with reference to FIGS. 9 to 11. As shown in FIG. 11, the signal current (I401) flowing through the signal wire 203 causes an AC magnetic field in the surroundings of the wire (Ampère's law). Further, due to the induced electromotive force caused by this AC magnetic field, the return current (I402) occurs in the GND wire 202 (Faraday's Law). Similarly, the signal current (I401) flowing through the signal wiring pattern 301 provided on the surface of the interposer causes an AC magnetic field in the surroundings of the signal wiring pattern 301, and the return currents (I402) (a current I_{B} flowing through the path 408 and a current I_{A} flowing through the path 407 in FIG. 11) occur in the GND wiring pattern 302 in the wiring layer 1 (207) and the GND wiring (not shown in the drawing) in the wiring layer 2 (212).

Similarly, the return current (I402) occurs in the outer GND through holes 209 near the signal through holes, in response to the signal current (I401) flowing through the signal through hole 208.

As shown in FIG. 11, there are three regions surrounded by the signal current (I401) and the return currents (I402) in Exemplary Embodiment 2: the region 1 (403), the region 2 (405), and a region 3 (406). Regarding the directions of the signal current flow and the return current flow surrounding each region, the currents flow in a clockwise direction in the region 1 (403) and in a counterclockwise direction in the regions 2 (405) and 3 (406). Out of the return currents, when the current flowing through the wiring layer 2 (212) is I_{A} (the current flowing through the path 407), the current flowing through the wiring layer 1 (207) is I_{B} (the current flowing through the path 408), and the areas of the regions 1 to 3 are ΔS1, ΔS2, ΔS3 respectively, the magnetic moment in sufficiently distant space, compared to the size of the IC package, can be expressed by the following equation (4) according to Biot-Savart law.

Mₘ=μ|I_{A}|(ΔS₁−ΔS₂−ΔS₃)+μ|I_{B}|(ΔS₁−ΔS₂) Equation (4)

Therefore, the AC magnetic fields generated in the surrounding space are reduced according to the area of the region 3 and the amount of the return currents I_{A} and I_{B}. As a result, the transmission loss of a high-speed signal can be reduced and electromagnetic radiation (a.k.a. radiation noise) can be decreased.

In Exemplary Embodiment 1, the generation of the AC magnetic field is suppressed by adjusting the areas of the two current loops: the regions 1 (403) and 2 (404). However, the solution is not limited to adjusting the two current loops, and as described in Exemplary Embodiment 2, considering the fact that there are a plurality of return paths for a signal current path, it is possible to let each return path intersect (cross-over) with the signal path so that the magnetic fields caused by these current loops are suppressed.

Further, as in Exemplary Embodiment 1, it is not necessary to dispose the signal current path 401 and each of the current return paths 402 on exactly the same plane in Exemplary Embodiment 2, and even in the cases where these paths cannot be on the same plane in the strict sense for reasons related to the mounting process, the effects can be obtained as long as the signal current path 401 and each of the current return paths 402 intersect at the middle and they are directed so that the magnetic fields essentially cancel each other.

### COMPARISON WITH PRIOR ARTS

In order to compare the prior arts with the present invention, the results of analyses performed by the present inventor on the signal current and the current return paths and the generation of the AC magnetic field in Patent Documents 1 to 3 described above will be presented.

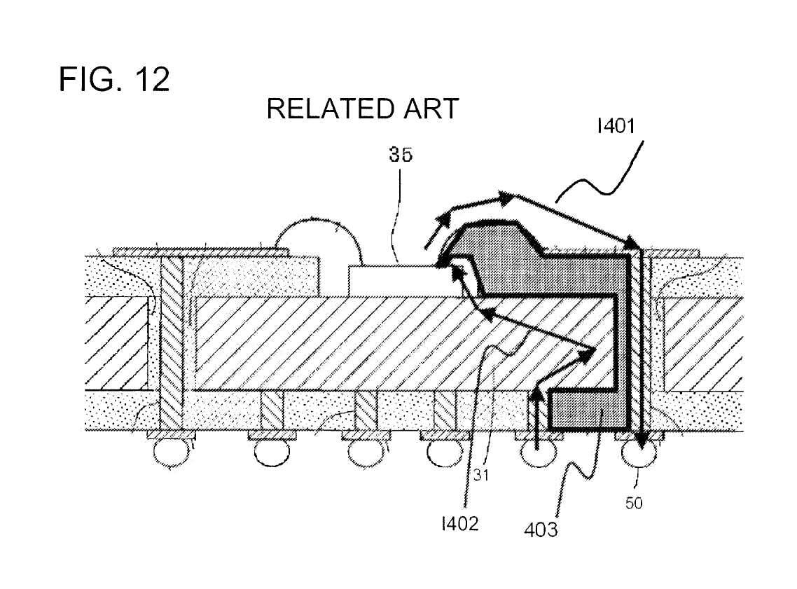

FIG. 12 is a diagram of the analysis performed by the present inventor on the signal current and the return current in Patent Document 1. In FIG. 12, the signal current (I401) flows from the semiconductor chip 35 to the solder ball (external connection signal terminal) 50 via bonding wires and signal through holes. Meanwhile, the return current (I402) is thought to flow from a solder ball adjacent to the external connection signal terminal 50 to the semiconductor chip 35 via the ground core (metal core) 31. Therefore, the paths through which the signal current (I401) and the return current (I402) flow do not intersect with each other at the intermediary, and a current loop formed by the signal current (I401) and the return current (I402) flows around the region 1 (403) in a clockwise direction. As a result, the signal current and the return current cause an AC magnetic field in Patent Document 1.

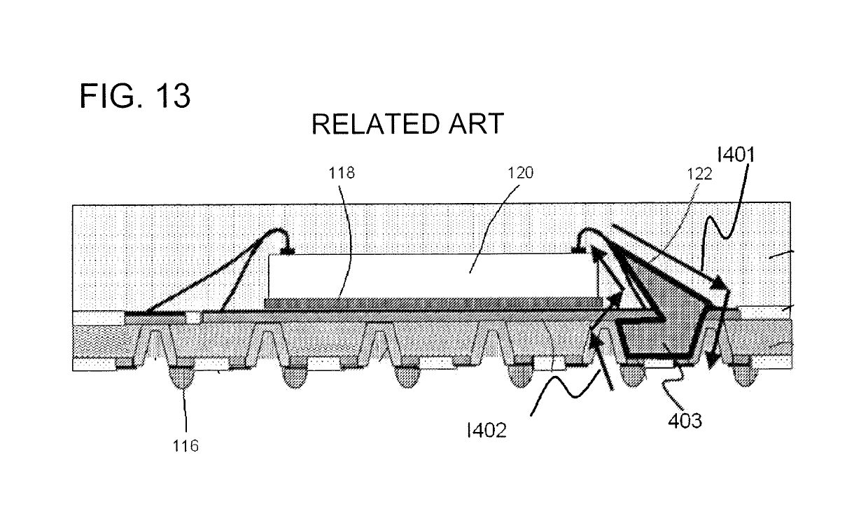

FIG. 13 is a diagram of the analysis performed by the present inventor on the signal current and the return current in Patent Document 2. In FIG. 13, the signal current (I401) flows from the circuit element (semiconductor chip) 120 to the corresponding solder ball (external connection signal terminal) 116 via the bonding wire 122. Meanwhile, the return current (I402) is thought to flow from a solder ball (external connection GND terminal) 116 disposed adjacent to the external connection signal terminal to the semiconductor chip 120 via the bonding wire. Therefore, the paths through which the signal current (I401) and the return current (I402) flow do not intersect with each other at the middle, and a current loop formed by the signal current (I401) and the return current (I402) flows around the region 1 (403) in a clockwise direction. According to Patent Document 2, it may be possible to make the area of the region 1 (403) small, however, it is impossible to completely eliminate the region 1 (403) and the signal current and the return current cause an AC magnetic field.

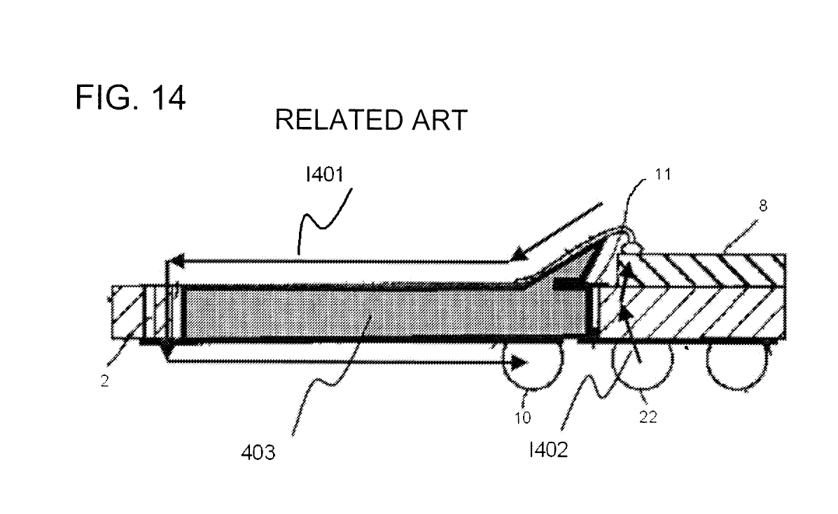

FIG. 14 is a diagram of the analysis performed by the present inventor on the signal current and the return current in Patent Document 3. In FIG. 14, the signal current (I401) flows from the semiconductor chip 8 to the corresponding solder ball (external connection signal terminal) 10 via a wiring on a BGA substrate and the through hole 2. Meanwhile, the return current (I402) is thought to flow from the solder ball (external connection GND terminal) 10 disposed adjacent to the external connection signal terminal to the semiconductor chip 8 via the bonding wire. Therefore, the paths through which the signal current (I401) and the return current (I402) flow do not intersect with each other at the intermediary, and a current loop formed by the signal current (I401) and the return current (I402) flows around the region 1 (403) in a counterclockwise direction. As a result, the signal current and the return current cause an AC magnetic field in Patent Document 3.

As described above, none of Prior Arts 1 to 3 has the magnetic fields caused by the current loop formed by the signal wiring and the return path wiring cancel each other by having the signal wiring and the return path wiring intersect with each other.

Further, in each of the exemplary embodiments described above, three or four layers of the wiring layers are provided on the interposer, however, the number of the wiring layers is not limited to these. It is preferable that two or more wiring layers be provided.

According to the present invention, in a semiconductor device having the semiconductor chip (205) and the interposer (206) on which the semiconductor chip is mounted, the interposer (206) comprises the first wiring pattern (301) and the second wiring pattern (302) respectively connected to the external terminals (211A and 211B) formed on the interposer; the first and the second wiring patterns are disposed adjacent to each other on the same plane layer of the interposer; the first wiring pattern has the first stitch (220) to which one end of the first bonding wire (203) is connected; the second wiring pattern (302) has the second stitch (220) to which one end of the second bonding wire (202) is connected; the other end of the first bonding wire is connected to the signal pad of the semiconductor chip; the other end of the second bonding wire is connected to either the ground pad or the power supply pad of the semiconductor chip; and the first stitch is disposed closer to the semiconductor chip than the second stitch is.

According to the configuration described above, it is possible to have the signal wiring and the return path wiring intersect (cross-over) with each other and have the magnetic fields caused by the current loop formed by the signal wiring and the return path wiring cancel each other.

Therefore, the signal wiring pattern 301 and the GND wiring pattern 302 should be formed adjacent to each other on the same plane layer, and they may be formed on any wiring layer of the interposer (206).

Further, the return path wiring (Wire 402) may be a power supply wiring instead of the GND wiring.

The following modes are possible in the first aspect (Mode 1).

### Mode 2

The signal wiring includes a first bonding wire connecting the first pad and a first wiring pattern provided on a semiconductor chip mounting surface of the interposer; the return path wiring includes a second bonding wire connecting the second pad and a second wiring pattern provided on the semiconductor chip mounting surface; the first wiring pattern and the second wiring pattern are disposed adjacent to each other on the same plane layer of the interposer; the first wiring pattern comprises a first stitch to which the first bonding wire is connected; the second wiring pattern comprises a second stitch to which the second bonding wire is connected; and the first stitch is disposed closer to the semiconductor chip than the second stitch is.

### Mode 3

The first bonding wire and the second bonding wire are configured so that one of them is positioned lower than the other and the former has a length shorter than that of the latter.

### Mode 4

The first external terminal and the second external terminal are provided on the opposite surface of the semiconductor chip mounting surface of the interposer, and the signal wiring and the return path wiring intersect with each other in a wiring pattern provided on the semiconductor chip mounting surface.

### Mode 5

The interposer on which the semiconductor chip is mounted is a multilayered interposer, and the signal wiring and the return path wiring are disposed so as to intersect with each other, in any wiring layer of the multilayered interposer.

### Mode 6

The first external terminal and the second external terminal are provided on the opposite surface of the semiconductor chip mounting surface of the multilayered interposer, and the signal wiring and the return path wiring are disposed, so as to intersect with each other, in any wiring layer of the multilayered interposer other than the opposite surface.

### Mode 7

A current loop formed the signal wiring and the return path wiring is divided into two regions by the intersection and the cross sectional areas of the two regions are essentially equal to each other.

### Mode 8

A return path wiring is connected from the second external terminal to the second pad through a plurality of routes, the return path of each of the routes and the signal wiring are provided essentially on the same plane, and the signal wiring and each return path intersect with each other at the intermediary so that the total sum of magnetic fields caused by current loops by the signal wiring and each of the return path becomes small.

### Mode 9

The return path wiring comprises a wiring connected to a ground or power supply.

In the second aspect (Mode 10), the following further modes are possible.

### Mode 11

The signal pad and any one of the ground pad and power supply pad are disposed adjacent to each other on the semiconductor chip.

### Mode 12

Any one of ground pad and power supply pad is connected to a ground wiring or power supply wiring of the interposer via the second wiring pattern.

### Mode 13

Any one of the ground pad and power supply pad is connected to a ground plane or power supply plane of the interposer via the second wiring pattern.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device, comprising:
an interposer;
a semiconductor chip mounted on the interposer;
a first wiring pattern formed on the interposer, the first wiring pattern including a first contact coupled to a bonding wire from the semiconductor chip and a second contact coupled to an external terminal of the interposer; and
a second wiring pattern formed adjacent to the first wiring pattern on the interposer, the second wiring pattern including a third contact coupled to another bonding wire from the semiconductor chip and a fourth contact coupled to another external terminal of the interposer,
wherein the first contact is closer to the semiconductor chip than the third contact.

2. The semiconductor device according to claim 1, wherein the first contact is closer to the semiconductor chip than the second contact, and
wherein the fourth contact is closer to the semiconductor chip than the third contact.

3. The semiconductor device according to claim 2, wherein, in the semiconductor device, a signal path and a return path cross each other without an electrical contact at the first and the second wiring patterns.

4. The semiconductor device according to claim 1, wherein the semiconductor chip includes a signal pad coupled to the bonding wire.

5. The semiconductor device according to claim 4, wherein the semiconductor chip further includes a ground pad coupled to the another bonding wire.

6. The semiconductor device according to claim 5, wherein the ground pad is placed adjacent to the signal pad on the semiconductor chip.

7. The semiconductor device according to claim 6, wherein the another external terminal is placed adjacent to the external terminal.
